(19) United States
(12) Patent Application Publication
(10) Pub. No.: US 2008/0068049 A1
(43) Pub. Date: Mar. 20, 2008

(54) Current-regulated, bootstrapped-biased, high to low impedance signal-buffer/output-driver for audio electronics

(76) Inventor: Alexander George Welti, Nashville, TN (US)

Correspondence Address: ALEXANDER GEORGE WELTI, 3668-B CENTRAL PIKE, HERMITAGE, TN, 37076, US

(21) Appl. No.: 11/900,490

(22) Filed: Sep. 11, 2007

Related U.S. Application Data
(60) Provisional application No. 60/845,305, filed on Sep. 18, 2006.

(51) Int. Cl. H03K 3/00

(52) U.S. Cl. 327/108

(57) ABSTRACT

An audio frequency buffer device comprising a unique arrangement of electronic elements, intended long battery operation, consisting of the current-buffer stage (18) with the current regulator (30) and the boot-strapped bias arrangement (16); and the current-driver stage (20) with the current regulator (32); the combination of two current regulators (30) and (32) gives improved distortion and lower noise specifications; and the boot-strapped bias arrangement (16) gives improved impedance specifications over previous designs.

### CROSS-REFERENCE TO RELATED APPLICATIONS

This application claims the benefit of provisional patent application Ser. No. 60/845,305, filed 2006 Sep. 18 by the present inventor.

### FEDERALLY SPONSORED RESEARCH

Not Applicable

### SEQUENCE LISTING OR PROGRAM

Not Applicable

### BACKGROUND OF THE INVENTION

1. Field of Invention

This invention generally relates to electronic musical instruments, specifically to improving the electrical integrity and quality of audio signal produced by transducer devices.

2. Prior Art

Since the advent of electronically reproduced or amplified audio signals there has been a need to convert the acoustic sounds produced by the musical instrument into an electronic signal for recording or amplification. Normally, an audio engineer would use a transducer, such as a microphone or magnetic pick-up device, mounted near, on or inside the musical instrument. The nature of these transducer devices, especially magnetic pick-ups for stringed instruments, require that they have high output impedances in order to be sensitive enough to produce a useable electronic signal. However, the transducer's high output impedance limits the capability of the pick-up device and compromises its ability to drive electrical loads, such as long hook-up cables with high capacitance or the relatively low impedance input stages commonly found in audio electronics. Therefore, to preserve the original audio signal in purest form these electronic pick-up devices require specialized high input impedance preamplifiers and relatively short high quality, low capacitance hook-up cables. Also, any device used for signal conditioning between the pick-up and preamp, such as an audio equalizer or effects box for example, requires careful consideration of impedances and electrical loading characteristics.

In order to help preserve the original audio signal from the pick-up device, a buffer device can be used. However, previous attempts to implement a buffer device have met with incomplete success. Although, previous attempts have helped, by achieving the desired somewhat higher input impedances and somewhat lower output impedances, which offer certain benefits and electrical advantages, consumers complain these devices also have undesirable side-effects and disadvantages, for example:
(a) They are known to introduce some unacceptable tonal-coloration. The ideal buffer device should preserve the original audio signal in the purest form and not add any hint of its own character to the signal.
(b) They add some unwanted noise. The ideal buffer device should add as little of its own noise as possible. Once noise is added to the original signal it is difficult to remove without also removing some of the desired signal.
(c) They introduce some signal distortion. The ideal buffer device should not distort the original signal unnecessarily. Unlike noise, once distortion occurs to the original signal it is impossible to remove.

In many situations these disadvantages are enough to out-weigh the benefits of these devices, and so they have not been widely accepted.

In addition, buffer devices require power. In providing power to the buffer device one must take the following into consideration: Optimal performance of the buffer device can best be obtained by locating a buffer device at or near the pick-up device so that the hook-up cable between the pick-up device and the buffer device is minimized. Battery operation is then desirable because the pick-up is normally mounted on or inside a handheld musical instrument and consumer testimony reveals that adding external power cords would hamper the musician's movements. The battery needs to be small enough to fit tight spaces inside instruments. Also, musicians and audio engineers need to be confident that the battery will not run-down and interrupt the signal during a performance. The buffer could be mounted externally to facilitate checking and changing batteries. However, externally mounted buffer designs compromise the original signal because they cannot address the loading effects of the hook-up cables used to connect the pick-up device to the buffer. Furthermore, as noted with external power, adding an external buffer device with hook-up cables would further hamper the musician's movements. In the past, designs based on Field Effect Transistors (FETs) used less power which made battery power feasible, however FETs are known introduce more tonal-coloration and distortion. Better sounding designs in the past used op-amps, however these required more power which meant shorter battery life or required the use of external power supplies. With thoughtful consideration these problems were immediately noted.

### BACKGROUND OF INVENTION

### Objects and Advantages

Accordingly, I have invented an improved buffer device with:
Extremely high audio quality. This device adds virtually no undesirable signal-coloration, distortion or noise. This device has a new novel circuit design which produces a quality of specifications not achieved in previous buffer devices.
Extremely high input impedance. This device's new novel circuit design achieves an input impedance which is many times greater than previous buffer devices could reliably provide.
Extremely low power consumption. This device can be operated with battery power for several hundred hours making it practical to locate the buffer with the pick-up device, often internally in an instrument, which eliminates the need for hook-up cables.
   Other objects and advantages are:
Elimination of counter Electro-Motive-Force (EMF) to the pick-up device. The extremely high input impedance draws very little current from the pick-up device thus reducing counter EMF and allowing the pick-up device to operate at full potential.
Provision of low impedance output drive capability for easy interfacing to a variety of common audio equipment.
Additionally, the new novel circuit design provides for a passive signal path which allows signal to pass, albeit un-buffered, if the battery were to expire during a performance, thereby reducing the worry of a show-stopping interruption.

Further objects and advantages of my invention will become apparent from a consideration of the drawings and ensuing description.

### SUMMARY

This CURRENT-REGULATED, BOOTSTRAPPED-BIASED, HIGH TO LOW IMPEDANCE SIGNAL-BUFFER/OUTPUT-DRIVER DEVICE FOR AUDIO ELECTRONICS comprises a unique arrangement of electronic elements which provide extremely high audio signal quality, extremely high input impedance, extremely low power consumption, counter EMF elimination, very low impedance output drive capability and a mode of passive operation should the battery expire during a performance.

### DRAWINGS

### Figures

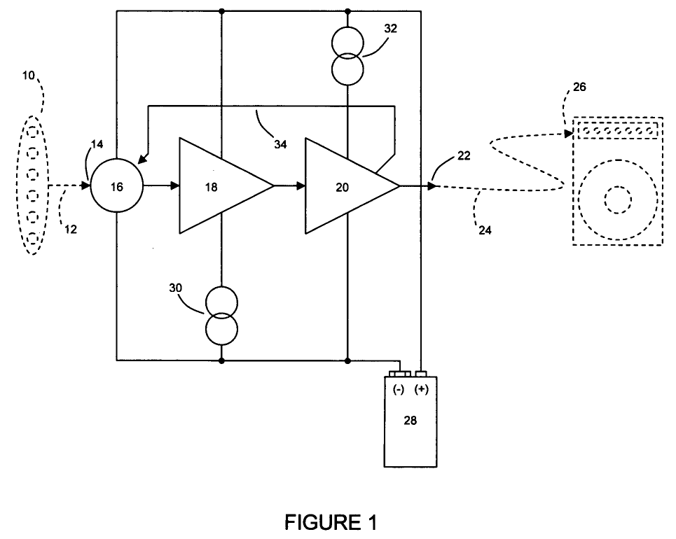

FIG. 1 shows a block diagram of the device with representative input and output devices.

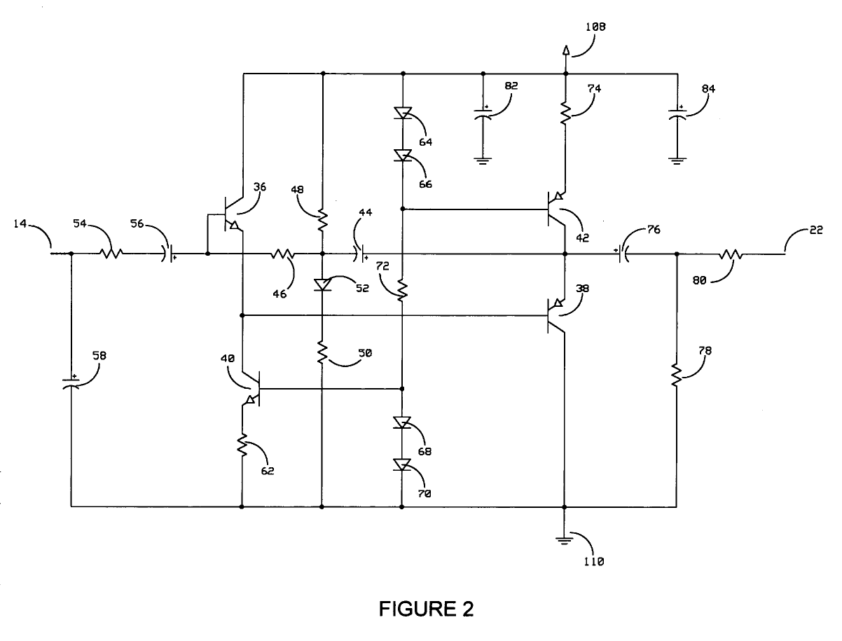

FIG. 2 is a detailed schematic of the preferred embodiment of the device.

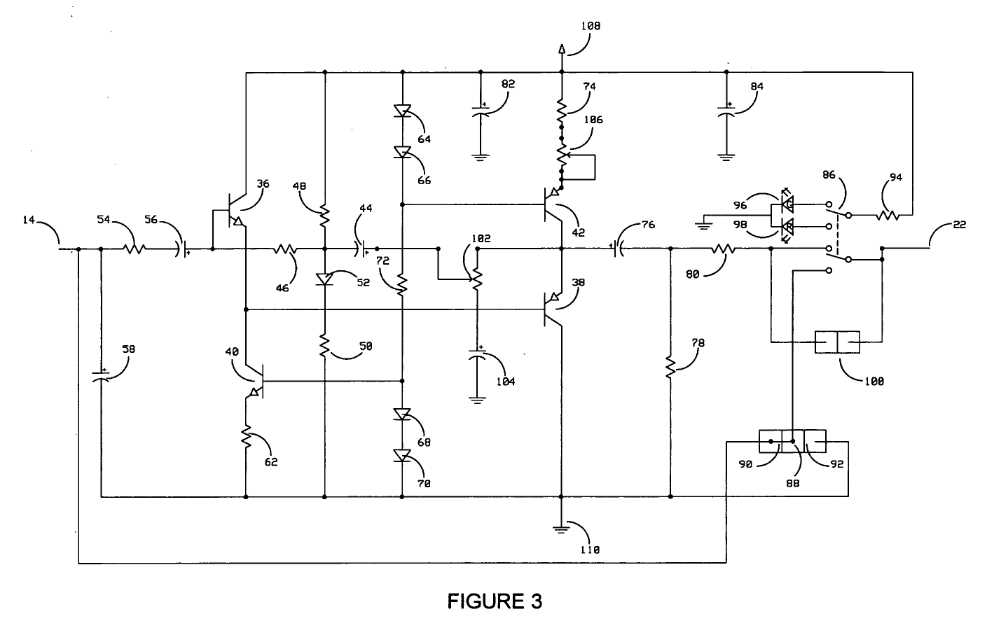

FIG. 3 is a detailed schematic for the alternative embodiments of the device.

### REFERENCE NUMERALS

| | |
|---|---|
| 10 | Pick-up Device |
| 12 | Input Wire |
| 14 | Input |
| 16 | Bootstrapped-Bias Stage |
| 18 | Current-Buffer Stage |
| 20 | Current-Driver Stage |
| 22 | Output |
| 24 | Long hook-up Cable |
| 26 | Audio Equipment Input |
| 28 | Battery |
| 30 | Regulator for Current-Buffer Stage |
| 32 | Regulator for Current-Driver Stage |
| 34 | Sample of Output Signal |
| 36 | Transistor NPN |
| 38 | Transistor PNP |
| 40 | Transistor NPN |
| 42 | Transistor PNP |
| 44 | Capacitor |
| 46 | Resistor |
| 48 | Resistor |
| 50 | Resistor |
| 52 | Diode |
| 54 | Resistor |
| 56 | Capacitor |
| 58 | Capacitor adjustable |
| 62 | Resistor |
| 64 | Diode |
| 66 | Diode |
| 68 | Diode |
| 70 | Diode |
| 72 | Resistor |
| 74 | Resistor |
| 76 | Capacitor |
| 78 | Resistor |
| 80 | Resistor |
| 82 | Capacitor |
| 84 | Capacitor |
| 86 | DPDT Switch |
| 88 | Link Option |
| 90 | Bypass Option |
| 92 | Mute Option |
| 94 | Resistor |
| 96 | LED |
| 98 | LED |
| 100 | Link Option |
| 102 | Variable Resistor |
| 104 | Capacitor |
| 106 | Variable Resistor |
| 108 | Battery (+) |
| 110 | Battery (−) |

### DETAILED DESCRIPTION

### Preferred Embodiment

### FIGS. 1, 2

A preferred embodiment of the current-regulated, bootstrapped-biased, high to low impedance signal-buffer/output-driver device for audio electronics is illustrated in block diagram form in FIG. 1. An external pick-up device 10 generates an electronic audio signal which is connected with a short input wire 12 directly to an input 14. A bootstrapped-bias circuit 16 applies a DC bias voltage to the signal. The signal plus the DC bias voltage is introduced to a current-buffer stage 18 which feeds a current-driver stage 20. The current-driver stage 20 is connected to an output 22 which is used to drive a long hook-up cable 24 and a subsequent audio equipment input 26. The device can be powered by a battery 28. Each stage has an independent current regulator 30 and 32. A sample of the output signal 34 feeds bias circuit 16 and also provides a passive signal path between the input and the output when the device is not powered on.

With reference to FIG. 2, the invention is an electronic buffer/driver device. This device consists of a two stage current buffer/driver based around a transistor 36, used as an emitter follower input buffer, and a transistor 38, used as an emitter follower output driver; but with two novel innovations. The first innovation being that currents through transistor 36 and transistor 38 are regulated by a transistor 40 and a transistor 42 respectively; this provides greatly improved distortion specifications. The second innovation being the use of a bootstrapped-bias arrangement, made-up by a capacitor 44, resistors 46, 48, 50, and a diode 52; this greatly increases the input impedance at signal frequencies of interest. More common biasing arrangements would have limited the input impedance to the value of resistor 48 in parallel with resistor 50. Normally, one would try to increase these resistors to increase input impedance, but doing that compromises the performance of transistor 36. The bootstrapped bias innovation allows ideal biasing and very high input impedance. The bootstrapped bias arrangement in the current embodiment is capable of achieving above 250,000,000 ohms input impedance at signal frequencies of interest and the output driver less than eight ohms output impedance. I have chosen conservative operating parameters within these limits. This conservative approach is done mainly to cater to the real world needs of the consumer. For example: lowering power consumption for longer battery life, building in circuit protection for robustness and accommodating the wider tolerances of less expensive components.

### OPERATION

### Preferred Embodiment

### FIG. 2

A resistor 54 limits DC leakage current through a capacitor 56 in the event that an input 14 from the pick-up device is short circuited. Otherwise, leakage current through capacitor 56 would cause undesirable noise.
Capacitor 56 blocks the bias voltage to the input. This prevents current flowing back to the pick-up device and also keeps the bias voltage from being influenced or loaded by the pick-up device. Capacitor 56 is selected to be very low leakage. Capacitor 56 is chosen to block at least Vcc/2 and to pass frequencies of interest (Xc calculated to be <<than the output impedance of the pick-up device).
Resistors 46, 48, 50, and diode 52 make-up the bias network for transistor 36. Ideally; Bias Voltage=((Vcc/2)+0.3V) accounting for the diode drop in transistor 36. The bias network current should provide good stiff biasing to transistor 36 to optimize performance. However, have consideration that too much bias current will unnecessarily drain power. Typically, transistor 36 will have a current gain of more than 200 so the bias current drawn will typically be 200 times less than the current flowing in transistor 36. I have chosen to set the current in the bias circuit 10 times higher than this to make it stiff. The current in transistor 36 was found to be no more than 0.3 mA, so the bias draw will be at most 1.5 uA through resistors 46, and 48. The current through resistors 48, and 50 should be set to at least 15 uA. Optimizing for 9V battery operation, we want good bias down to 4.8V when the battery is weak. Leaving 4.2V to be dissipated at 15 uA, resistors 48 and 50 should combine to make 280K ohms or less. To keep the bias voltage close to ((Vcc/2)+0.3V) as the battery drains, the voltage dropped across resistor 46 should be kept low; a 200K resistor should drop no more than 0.3V. Therefore, the voltage drop through resistor 48 should be 0.3V less, and the voltage drop across resistor 50 should be 0.3V more than ((Vcc/2)−0.3V) accounting for 0.6V drop across diode 52. Using standard available values, resistor 48=130K ohms and resistor 50=150K ohms gives the best division.
Resistor 46 is part of the bootstrapped bias arrangement. It is bootstrapped by capacitor 44 to create a virtually infinite resistance at signal frequencies. This arrangement allows the bias to be stiff enough to get good performance from transistor 36 without loading down the signals of interest. At signal frequencies resistor 46 will look infinite in theory because capacitor 44 holds the voltage across resistor 46 close to 0V. 0V across resistor 46 means zero current flow; as if resistor 46 were an infinite impedance. The virtual impedance of resistor 46 in parallel with the impedance of transistor 42 and a capacitor 58 (if installed) becomes the overall input impedance of the device.
Transistor 36 and transistor 38 are configured as two emitter follower stages with high current gain. A typical transistor with gain of 200 means that the input impedance at the base of transistor 36 will be 40,000 times greater than any load connected to the emitter of transistor 38. An output 22 is intended to be connected to audio equipment with input impedances of typically greater than 10K ohms; therefore, the impedance looking into transistor 36 will be greater than 400 M ohms. The output impedance of transistor 38 is potentially 40,000 times less than the output impedance of the pick-up device connected at input 14. This is affected by the current regulation set by transistor 42 and a limiting resistor 80.
Transistor 40 acts as a regulated current source for transistor 36. The beta of transistor 36 varies slightly with current and this variance introduces distortion. Transistor 40 regulates current in transistor 36 and greatly reduces distortion. The impedance of a current source is virtually infinite, so transistor 40 does not load the output of transistor 36.
A resistor 62 sets the current in transistor 36 and transistor 40 (I=0.6V/(resistor 62)), additional bias current (appx 0.01 mA) drawn off by transistor 38 also flows through transistor 36. In fact, resistor 62 was chosen to set the current in transistor 36 to be 10 times the draw of transistor 38 in order to provide a stiff bias for transistor 38.
Diodes 64, 66, 68, 70, and a resistor 72 provide bias for transistor 40 and transistor 42. The current through resistor 72 should be about 10 times the bias current drawn by transistor 40 and transistor 42, or appx 0.1 mA. Considering a weak battery scenario of 4.8V, 2.4V remains across resistor 72 so a 24K resistor can be chosen.
Transistor 38 feeds the bootstrap capacitor 44 in addition to driving the output 22. It also negates the voltage shift of the emitter junction of transistor 36 and leaves no voltage across capacitor 44.
Transistor 42 acts as a regulated current source for transistor 38. The beta of transistor 38 varies slightly with current and this variance introduces distortion. Transistor 42 regulates current in transistor 38 and greatly reduces distortion. The impedance of a current source is virtually infinite, so transistor 42 does not load the output of transistor 38.
A resistor 74 sets the current in transistor 42 and transistor 38 to about 2.5 mA.
Capacitor 44 is the bootstrap capacitor. Capacitor 44 keeps the voltage across resistor 50 near 0V creating very high input impedances. Capacitor 44 prevents the voltage in the bias circuit from being loaded down by the low impedance output of transistor 38. Capacitor 44 should be able to cope with Vcc/2 during the power cycle, but normally has no voltage across it. (Xc<<than the impedance of the bias resistors 48 and 50 in parallel)
A capacitor 76 removes DC voltage from the output. It should be low leakage and is chosen to block at least Vcc/2 and to pass frequencies of interest (Xc<<than the load impedance of any device connected to the output 22)
A resistor 78 references the output of capacitor 76 to ground when the output is disconnected, since some loads connected to output 22 could be high impedance resistor 78 should not be omitted unless the load is to be permanently connected at output 22 and designed to cope with leakage current from capacitor 76.
A resistor 80 provides current limiting to protect against accidental short circuit condition at output 22. If the output is to be permanently connected to the following device, resistor 80 can be reduced to 0 ohms to provide lower output impedance.
A capacitor 82 provides power filtering.
A capacitor 84 provides additional power filtering.
A passive signal path exists connecting the input to the output comprising resistor 54, capacitor 56, resistor 46, capacitor 44, capacitor 76 and resistor 80. This passive signal path allows audio to continue passing through the device when power is removed or should the battery fail. The passive signal will be somewhat attenuated, however, it will still be useable and preferable to loosing the signal altogether as with previous designs once power was removed.

### DESCRIPTION

### Alternative Embodiments

### FIG. 3

An alternate embodiment includes all parts and features of the previously discussed preferred embodiment. Additional options allow for the tailoring of the device to specific requirements. Capacitor 58 may be altered to condition the input signal. The addition of a switch 86 and LED indicators 96 and 98 allows the user to either bypass signal around the circuit or mute the signal at output 22 dependent on the position of a link option 88. The input impedance may be made adjustable with a variable resistor 102. The output impedance may be made adjustable with a variable resistor 106.

### OPERATION

### Alternative Embodiments

### FIG. 3

Capacitor 58 is optional to simulate the effects of adding a length of cable (33 pf simulates 1 foot) between the preceding pick-up device and the input 14.

Normally this is not desirable, but a discriminating advanced user may want this ability to recreate certain characteristics. For example: A 20 foot long electric guitar cable would be represented by a 660 pf capacitor. This creates a resonant tank circuit with the inductance of a magnetic pick-up device. A typical pick-up device with 2.0 henrys inductance will resonant with a 20 ft cable at:

F=1/2π\sqrt{2 H·660 pf}

F=4.4 KHz
The resonant frequency may be boosted several dB. At the same time the overall response rolls-off at higher frequencies. Capacitor 58 would also shunt any RF interference that may try to enter the input 14.
A switch 86 is optional to bypass around the circuit or mute the output of the device. “Bypass” or “Mute” is selected according to the position of link 88. Selecting a “Bypass” position 90 feeds signal from the input 14 to switch 86 and on to the output 22. This would be useful to demonstrate the effect of the invention to a potential customer. Selecting a “Mute” position 92 feeds ground to switch 86 and on to the output 22. This would be useful if a musician wanted to silence the output for any reason during a performance.
A resistor 94 limits current in indicators 96 and 98 which give a visual status of the position of switch 86.
If switch 86 is not installed, a link 100 should be fitted; otherwise link 100 should be omitted.
Variable resistor 102 and a capacitor 104 are optional to provide a way to adjust the overall input impedance. This allows the advanced user to adjust the input impedance to recreate the loading effect of a particular situation. Normally, you would simply want the highest impedance. If omitting these parts, the emitter of transistor 38 should be connected to capacitor 44. The input impedance can be chosen between nearly 0 ohms up to 200 M ohms by values selected for resistors 46, 48 and 50. For example, setting these resistor to 33K will allow the input impedance to be adjusted from 50K ohms to 10 M ohms which neatly covers a range to simulate the impedance of all electric guitar amplifier and FX pedal devices.
Variable resistor 106 is optional to provide a way to adjust the overall output impedance. This allows the discriminating advanced user to adjust the output impedance if they wanted to recreate the source impedance of a particular instrument. Normally, you would simply want the lowest possible impedance. If this option is included change resistor 74 to 27 ohms. If this option is omitted, resistor 74 should be connected to the emitter of transistor 42 and resistors 74 should be set to 240 ohms. This option allows the output impedance to be varied from 20 ohms to 8.6K ohms.

### CONCLUSION, RAMIFICATIONS, AND SCOPE

Accordingly the reader will see that with the novel use of the current-regulation, and bootstrapped-bias arrangement, I have provided a unique arrangement of electronic elements in a new buffer device which provides improved performance than previously obtainable, simultaneously including all the following advantages:
Higher audio signal quality than yet obtained in a buffer designed for musical instruments and audio pick-up devices. Having better tonal, noise and distortion specifications.
Much higher input impedance than previously successfully obtained, resulting in improved Counter EMF elimination. This feature being variable in the alternative embodiment.
Very low impedance output drive capability, allowing a greater ability to preserve the desired signal. This feature being variable in the alternative embodiment.
Extremely low power consumption, typically several hundred hours of operation on a single battery.
A mode of passive operation should the battery expire during a performance.

Although the above description contains many specifications, these should not be construed as limitations to the scope of the invention, but as illustrations of some of the presently preferred embodiments of this invention. For example, the current-regulated, bootstrapped-biased, high to low impedance signal-buffer/output-driver device for audio electronics would also be beneficial for uses outside of audio electronics where pick-up devices are used and require buffer devices to send signals to following devices, such as heart monitors, seismic detectors or mechanical position sensors used in automation.

Additionally, the current-regulated, bootstrapped-biased, high to low impedance signal-buffer/output-driver device for audio electronics could be included as a sub-circuit within another circuit, such as building the buffer device directly inside the pick-up device, directly inside the musical instrument, directly inside an effects pedal, directly inside an amplifier or directly inside any equipment that would benefit from having buffered inputs, buffered outputs or buffering between internal stages.

Also, the unique arrangement of electronic elements comprising the current-regulated, bootstrapped-biased, high to low impedance signal-buffer/output-driver device is not limited to the specific values stated in the preferred or alternate embodiments. Substituting different transistors, diodes, capacitors, resistors, materials or substances to tailor the circuit for specific applications would not be considered as a new invention. Some examples could be changes to affect the input impedance, changes to affect distortion, changes to affect noise, changes to affect battery life or substituting the preferred parts with more or less expensive parts.

Furthermore, the unique arrangement of electronic components comprising the current-regulated, bootstrapped-biased, high to low impedance signal-buffer/output-driver device for audio electronics could be miniaturized onto an integrated circuit for mass production, etc.

Thus the scope of the invention should be determined by the appended claims and their legal equivalents, rather than by the examples given.

1. A current-regulated, bootstrapped-biased, high to low impedance signal-buffer/output-driver device for audio electronics, comprising:
a current-buffer stage comprising a current regulator means;
a current-driver stage comprising a second current regulator means;
a bootstrapped-bias arrangement wherein a sample of the output is fed into the bias arrangement.

2. The device of claim 1, wherein said bootstrapped-bias arrangement comprises a means to adjust the sample size of said output fed into said bias arrangement.

3. The device of claim 2, wherein said second current regulator means comprises a means to adjust the output impedance.

4. The device of claim 3, wherein said device has a means to bypass the input to said output.

5. The device of claim 4, wherein said means has a status indicator means.

6. The device of claim 3, wherein said device has a means to mute said output.

7. The device of claim 6, wherein said means has a status indicator means.

8. The device of claim 3, wherein said means has a status indicator means.

9. The device of claim 2, wherein said device has a means to bypass the input to said output.

10. The device of claim 9, wherein said means has a status indicator means.

11. The device of claim 2, wherein said device has a means to mute said output.

12. The device of claim 11, wherein said means has a status indicator means.

13. The device of claim 2, wherein said means has a status indicator means.

14. The device of claim 1, wherein said second current regulator means comprises a means to adjust the impedance of said output.

15. The device of claim 14, wherein said means has a status indicator means.

16. The device of claim 1, wherein said device has a means to bypass the input to said output.

17. The device of claim 16, wherein said means has a status indicator means.

18. The device of claim 1, wherein said device has a means to mute said output.

19. The device of claim 18, wherein said means has a status indicator means.

20. A current-regulated, bootstrapped-biased, high to low impedance signal-buffer/output-driver circuit, comprising:
a current-buffer stage comprising a current regulator means;
a current-driver stage comprising a second current regulator means;
a bootstrapped-bias arrangement wherein a sample of the output is fed into the bias arrangement.
